(19) United States
(12) Patent Application Publication
(10) Pub. No.: US 2023/0197755 A1
(43) Pub. Date: Jun. 22, 2023

(54) IMAGE SENSOR

(71) Applicant: Samsung Electronics Co., Ltd., Suwon-si (KR)

(72) Inventors: Changyong UM, Seoul (KR); Jeongsoon KANG, Gumi-si (KR); Jeongjin LEE, Seoul (KR)

(73) Assignee: Samsung Electronics Co., Ltd., Suwon-si (KR)

(21) Appl. No.: 17/965,268

(22) Filed: Oct. 13, 2022

(30) Foreign Application Priority Data
Dec. 22, 2021 (KR) 10-2021-0184878

(51) Int. Cl. H01L 27/146; H01L 23/00

(52) U.S. Cl. CPC H01L 27/14634; H01L 24/08; H01L 27/14636; H01L 24/80; H01L 27/1469; H01L 2224/08145; H01L 2224/80006; H01L 2224/80895; H01L 2224/80896

(57) ABSTRACT

An image sensor may include a lower device on a lower substrate, an intermediate device on an intermediate substrate on the lower substrate, and an upper device on an upper substrate on the intermediate substrate. The lower device may include a logic transistor. The intermediate device may include at least one transistor. The upper device may include a photodiode and a floating diffusion region. The lower substrate, the intermediate substrate and the upper substrate may be stacked. The intermediate substrate may include a stack of a first semiconductor layer, a silicon oxide layer, and a second semiconductor layer pattern. An insulation pattern fills an opening at least partially defined by one or more inner surfaces of the first semiconductor layer. A buried insulation pattern fills a trench extending through the second semiconductor layer pattern.

### CROSS-REFERENCE TO RELATED APPLICATION

This application claims priority under 35 USC § 119 to Korean Patent Application No. 10-2021-0184878, filed on Dec. 22, 2021, in the Korean Intellectual Property Office (KIPO), the contents of which are incorporated by reference herein in their entirety.

### BACKGROUND

### 1. Field

Some example embodiments relate to image sensors and methods for manufacturing the same. More particularly, some example embodiments relate to stacked image sensors and methods for manufacturing the same.

### 2. Description of the Related Art

An image sensor may convert an optical image into an electrical signal. Recently, according to a development of a computer industry and a communication industry, a demand for the image sensor with improved performance may be increased in various fields such as digital cameras, camcorders, personal communication systems (PCS), game devices, security cameras and medical micro cameras.

The image sensor may include a charge coupled device (CCD) and a CMOS image sensor. The CMOS image sensor may have a simple driving method, and a signal processing circuit in the CMOS image sensor may be integrated into a single chip so that a product may be miniaturized. The CMOS image sensor may have little power consumption, so that the CMOS image sensor may be used to products with limited battery capacity. Meanwhile, as an electronic industry is highly developed, a size of the image sensor may be decreased. Therefore, various studies may be conducted to satisfy the demands for high integration of the image sensor.

### SUMMARY

Example embodiments provide an image sensor having good characteristics.

According to some example embodiments, an image sensor may include a lower device on a lower substrate, an intermediate device on an intermediate substrate on the lower substrate, and an upper device on an upper substrate on the intermediate substrate. The lower device may include a logic transistor. The intermediate device may include at least one transistor. The upper device may include a photodiode and a floating diffusion region. The lower substrate, the intermediate substrate and the upper substrate may be stacked. The intermediate substrate may include a stack of a first semiconductor layer, a silicon oxide layer, and second semiconductor layer patterns. The first semiconductor layer may include one or more inner surfaces at least partially defining an opening in the first semiconductor layer, and an insulation pattern may fill the opening. At least one sidewall surface of the second semiconductor layer pattern may at least partially define a trench extending through the second semiconductor layer pattern, and a buried insulation pattern fills the trench extending through the second semiconductor layer pattern.

According to some example embodiments, an image sensor may include a lower device on a lower substrate, a first insulating interlayer covering the lower device, an intermediate device on a first surface of an intermediate substrate on the lower substrate, a second insulating interlayer covering the intermediate device, an upper device on an upper substrate on the intermediate substrate, and a third insulating interlayer covering the upper device. The lower device may include a logic transistor. The intermediate device may include at least one transistor. The upper device may include a photodiode and a floating diffusion region. A surface of the first insulating interlayer and a surface of the second insulating interlayer may be bonded to each other. A second surface opposite to the first surface of the intermediate substrate and a surface of the third insulating interlayer may be bonded to each other. The intermediate substrate may include a stack of a first semiconductor layer, a silicon oxide layer, and second semiconductor layer patterns. At least one sidewall surface of the second semiconductor layer pattern may at least partially define a trench extending through the second semiconductor layer pattern, and a buried insulation pattern fills the trench extending through the second semiconductor layer pattern.

According to some example embodiments, an image sensor may include a lower device on a lower substrate, a first insulating interlayer covering the lower device, an intermediate device on a first surface of an intermediate substrate on the lower substrate, a second insulating interlayer covering the intermediate device, a first bonding pad pattern in the second insulating interlayer, an upper device on an upper substrate on the intermediate substrate, a third insulating interlayer covering the upper device, and a second bonding pad pattern in the third insulating interlayer. The lower device may include a logic transistor. The intermediate device may include at least one transistor. An upper surface of the first bonding pad pattern may be exposed by a first surface of the second insulating interlayer. The upper device may include a photodiode and a floating diffusion region. An upper surface of the second bonding pad pattern may be exposed by a first surface of the third insulating interlayer. A surface of the first insulating interlayer and a second surface opposite to the first surface of the intermediate substrate may be bonded to each other. The first bonding pad pattern and the second bonding pad pattern may be bonded to each other. The intermediate substrate may include a stack of a first semiconductor layer, a silicon oxide layer, and second semiconductor layer patterns. At least one sidewall surface of the second semiconductor layer pattern may at least partially define a trench extending through the second semiconductor layer pattern, and a buried insulation pattern fills the trench extending through the second semiconductor layer pattern.

In some example embodiments, the buried insulation pattern may be between the second semiconductor layer patterns of the intermediate substrate, so that the second semiconductor layer pattern may be formed to have a thickness of less than 1 μm. Therefore, a thickness of the intermediate substrate may be decreased, so that characteristics of the image sensor may be improved.

### BRIEF DESCRIPTION OF THE DRAWINGS

Example embodiments will be more clearly understood from the following detailed description taken in conjunction with the accompanying drawings. FIGS. 1 to 37 represent non-limiting, example embodiments as described herein.

FIG. 1 is a block diagram of an image sensor in accordance with some example embodiments;

FIG. 2 is a circuit diagram illustrating an example of a unit pixel included in a pixel array in accordance with some example embodiments;

FIG. 3 is a cross-sectional view illustrating an image sensor in accordance with some example embodiments;

FIG. 4 is a plan view illustrating a portion of an intermediate device formed on an intermediate substrate in the image sensor in accordance with some example embodiments;

FIG. 5 is a cross-sectional view illustrating a portion of an intermediate device formed on an intermediate substrate in the image sensor in accordance with some example embodiments;

FIGS. 6, 7, 8, 9, 10, 11, 12, 13, 14, 15, 16, 17, 18, 19, 20, 21, and 22 are cross-sectional views illustrating a method of manufacturing an image sensor in accordance with some example embodiments;

FIG. 23 is a cross-sectional view illustrating image sensors in accordance with some example embodiments;

FIG. 24 is a cross-sectional view illustrating a portion of an intermediate device formed on an intermediate substrate in the image sensor in accordance with some example embodiments; and

FIGS. 25, 26, 27, 28, 29, 30, 31, 32, 33, 34, 35, 36, and 37 are cross-sectional views illustrating a method of manufacturing an image sensor in accordance with some example embodiments.

### DETAILED DESCRIPTION

Hereinafter, some example embodiments of the inventive concepts will be described in detail with reference to the accompanying drawings.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular” with regard to other elements and/or properties thereof will be understood to be “perpendicular” with regard to the other elements and/or properties thereof within manufacturing tolerances and/or material tolerances and/or have a deviation in magnitude and/or angle from “perpendicular,” or the like with regard to the other elements and/or properties thereof that is equal to or less than 10% (e.g., a. tolerance of ±10%).

Elements and/or properties thereof (e.g., structures, surfaces, directions, or the like) that are “substantially parallel” with regard to other elements and/or properties thereof will be understood to be “parallel” with regard to the other elements and/or properties thereof within manufacturing tolerances and/or material tolerances and/or have a deviation in magnitude and/or angle from “parallel,” or the like with regard to the other elements and/or properties thereof that is equal to or less than 10% (e.g., a. tolerance of ±10%).

Elements and/or properties thereof (e.g., structures, surfaces, directions, or the like) that are “substantially coplanar” with regard to other elements and/or properties thereof will be understood to be “coplanar” with regard to the other elements and/or properties thereof within manufacturing tolerances and/or material tolerances and/or have a deviation in magnitude and/or angle from “coplanar,” or the like with regard to the other elements and/or properties thereof that is equal to or less than 10% (e.g., a. tolerance of ±10%)).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value include a tolerance of ±10% around the stated numerical value. When ranges are specified, the range includes all values therebetween such as increments of 0.1%.

As described herein, when an operation is described to be performed “by” performing additional operations, it will be understood that the operation may be performed “based on” the additional operations, which may include performing said additional operations alone or in combination with other further additional operations.

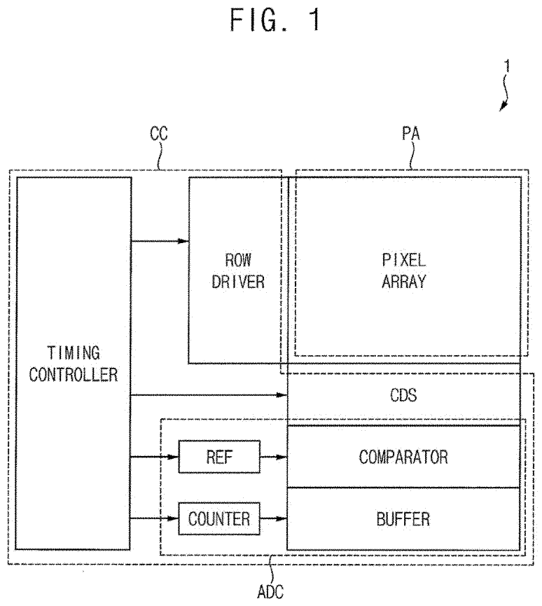

FIG. 1 is a block diagram of an image sensor 1 in accordance with some example embodiments. The image sensor 1 of FIG. 1 may be a CMOS image sensor.

Referring to FIG. 1, the image sensor 1 may include a pixel array PA and a signal processing unit CC. The pixel array PA may convert incident light to generate electrical signals. The pixel array PA may include a plurality of unit pixels (not shown) arranged in a matrix form. The pixel array PA may be driven by various driving signals, and may provide converted electrical signals to the signal processing unit CC.

The signal processing unit CC may process the electrical signals to generate image data. The signal processing unit CC may include a row driver, a correlated double sampler (CDS), an analog-to-digital converter (ADC), and a timing controller.

The row driver may be connected to each row of the pixel array PA, and may generate driving signals for driving each row. For example, the row driver may drive the plurality of unit pixels included in the pixel array PA, in a row unit.

The CDS unit may perform correlated double sampling by obtaining a difference between a reference voltage indicating a reset state of the unit pixels and an output voltage indicating a signal component corresponding to incident light using a capacitor, a switch, etc. Also, analog sampling signals corresponding to an effective signal component may be output. The CDS unit may include a plurality of CDS circuits connected to column lines of the pixel array PA, respectively, and may output the analog sampling signal corresponding to the effective signal component for each column.

The ADC unit may convert analog image signals corresponding to the effective signal component into a digital image signal. The ADC unit may include a reference signal generator REF, a comparator, a counter, and a buffer unit. The reference signal, e.g., a ramp signal having a constant slope may be generated, and the ramp signal may be provided as a reference signal of the comparator. The comparator may compare the analog sampling signal output from the CDS unit for each column with the ramp signal generated from the reference signal generator, and output comparison signals having respective transition points according to the effective signal components. The counter may generate a counting signal by performing a counting operation, and may provide the counting signal to the buffer unit. The buffer unit includes a plurality of latch circuits connected to the column lines, respectively. The buffer unit may latch the counting signal output from the counter in response to a transition of each comparison signal for each column, and may output the latched counting signal as the image data.

The timing controller may control operation timings of the row driver, the CDS unit, and the ADC unit. The timing controller may provide a timing signal and a control signal to the row driver, the CDS unit, and the ADC unit.

As described above with reference to FIG. 1, the image sensor 1 may perform analog double sampling. However, in some example embodiments, the image sensor 1 may perform digital double sampling (DDS). The digital double sampling refers to extracting the difference between two digital signals as an effective signal component after converting an analog signal for a reset component when a pixel is initialized and an analog signal for the signal component into digital signal, respectively.

As described herein, any devices, electronic devices, modules, units, and/or portions thereof according to any of the example embodiments, and/or any portions thereof (including, without limitation, the image sensor 1, the pixel array PA, the signal processing unit CC, the row driver, the CDS unit, the ADC unit, the reference signal generator REF, the comparator, the counter, the buffer unit, the timing controller, or the like) may include, may be included in, and/or may be implemented by one or more instances of processing circuitry such as hardware including logic circuits; a hardware/software combination such as a processor executing software; or a combination thereof. For example, the processing circuity more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, electronic devices, modules, units, and/or portions thereof according to any of the example embodiments.

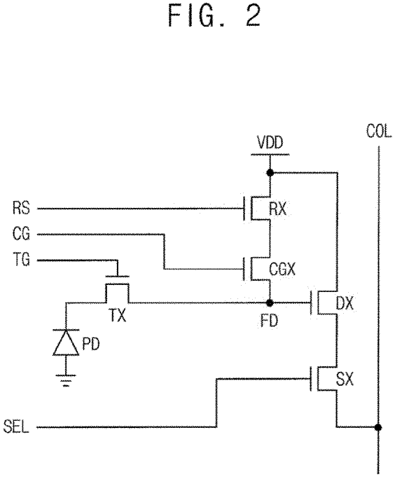

FIG. 2 is a circuit diagram illustrating an example of a unit pixel included in a pixel array (e.g., pixel array PA shown in FIG. 1) in accordance with some example embodiments.

Referring to FIG. 2, the unit pixel may include a photodiode PD as a photosensitive device, and a transfer transistor TX, a reset transistor RX, a dual conversion gain (DCG) transistor CGX, a drive transistor DX and a selection transistor SX as readout circuits.

The photodiode PD may receive light (e.g., visible light or infrared light) from the outside, and may generate a photo charge based on the received light. In some example embodiments, the unit pixel may include a phototransistor, a photogate, a pinned photodiode, or the like, together with or instead of the photodiode PD.

The photo charge generated by the photodiode PD may be transferred to a floating diffusion node FD through the transfer transistor TX. For example, when the transfer control signal TG has a first level (e.g., a high level), the transfer transistor TX may be turned on. Also, the photo charge generated by the photodiode PD may be transmitted to the floating diffusion node FD through the transfer transistor TX.

The drive transistor DX may serve as a source follower buffer amplifier, and may amplify a signal corresponding to the charge charged in the floating diffusion node FD. The selection transistor SX may transmit the amplified signal to the column line COL in response to a selection signal SEL. The floating diffusion node FD may be reset by the reset transistor RX. For example, the reset transistor RX may discharge the photo charge stored in the floating diffusion region FD at a constant cycle for the CDS operation in response to the reset signal RS. The DCG transistor CGX may switch to be operable in a low CG (conversion gain) mode or high CG (conversion gain) mode according to a CG signal.

FIG. 2 illustrates a unit pixel including one photodiode PD and five MOS transistors TX, RX, DX, SX and CGX. However, a unit pixel in accordance with some example embodiments may not be limited thereto.

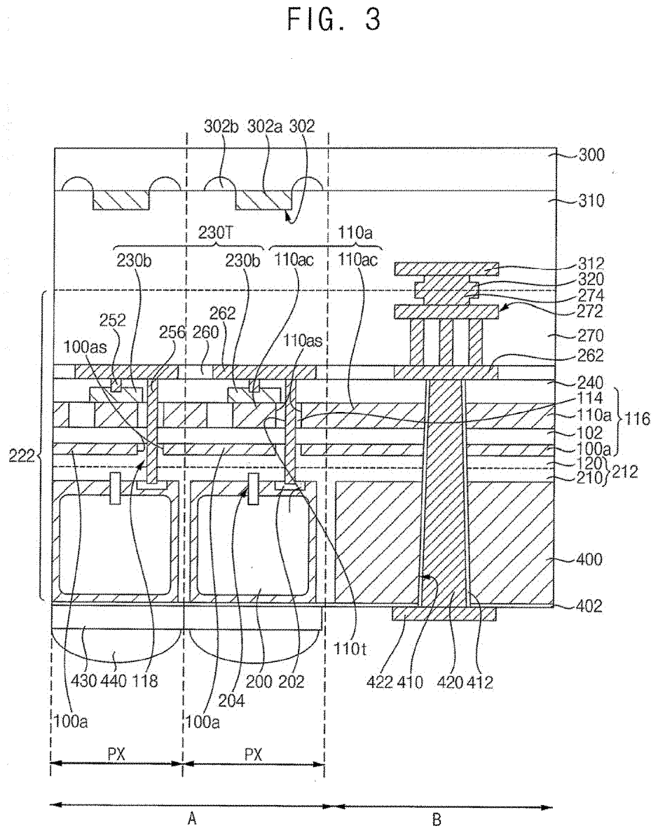

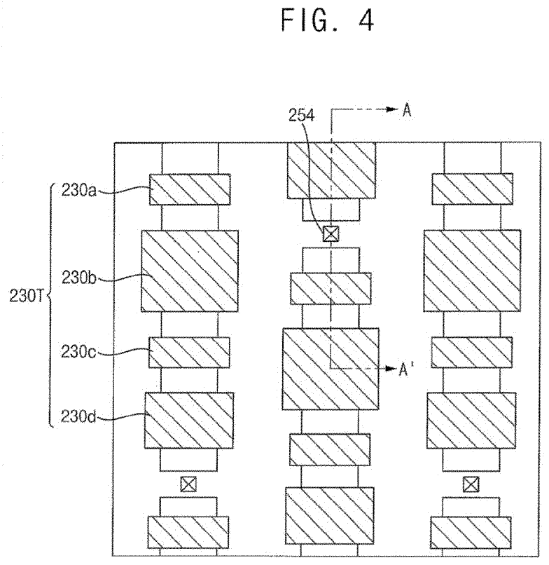

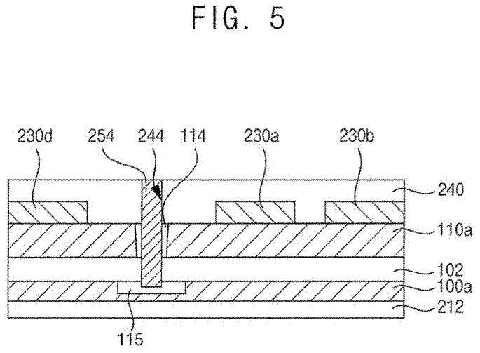

FIG. 3 is a cross-sectional view illustrating an image sensor (e.g., the image sensor 1 shown in FIG. 1) in accordance with some example embodiments. FIG. 4 is a plan view illustrating a portion of an intermediate device formed on an intermediate substrate in the image sensor (e.g., the image sensor 1 shown in FIG. 1) in accordance with some example embodiments. FIG. 5 is a cross-sectional view illustrating a portion of an intermediate device formed on an intermediate substrate in the image sensor (e.g., the image sensor 1 shown in FIG. 1) in accordance with some example embodiments.

In FIG. 4, only some contact plugs (i.e., second contact plugs) formed on the intermediate substrate are illustrated in order to avoid complication of a drawing. FIG. 5 is a cross-sectional view taken along the line A-A′ of FIG. 4.

Referring to FIG. 3, the image sensor may include a lower device formed on the lower substrate 300, an intermediate device formed on the intermediate substrate 116, and an upper device formed on the upper substrate 400. The image sensor may have a structure in which a lower substrate 300, an intermediate substrate 116, and an upper substrate 400 are bonded. The image sensor may be divided into a pixel array region A and a signal processing region B. In FIG. 3, the lower substrate 300 may be positioned at an uppermost portion and the upper substrate 400 may be positioned at a lowermost portion.

The lower substrate 300 may include a silicon substrate, a silicon germanium substrate, or the like.

The lower device may include logic transistors 302 and wiring (not shown) constituting a logic circuit. Particularly, the lower device may include a lower impurity region 302b formed in the lower substrate 300 and a lower gate 302a formed on the lower substrate 300. The lower gate 302a may include a gate insulation layer and a gate electrode.

A lower insulating interlayer 310 may be formed on the lower substrate 300 to cover the lower gate 302a. The lower insulating interlayer 310 may include silicon oxide.

A third connection wiring 312 may be formed in the lower insulating interlayer 310. The third connection wiring 312 may include lower vias and conductive patterns. Each of the lower vias and conductive patterns may include a barrier metal pattern and a metal pattern. In some example embodiments, the metal pattern may include tungsten (W), copper (Cu), aluminum (Al), etc., and the barrier metal pattern may include titanium, titanium nitride, tantalum, tantalum nitride, etc. In some example embodiments, each of the lower vias and the metal patterns may be formed in multiple layers.

A second bonding pad pattern 320 electrically connected to the third connection wiring 312 may be disposed in the lower insulating interlayer 310. A surface of the second bonding pad pattern 320 may be exposed by a surface of the lower insulating interlayer 310. The surface of the second bonding pad pattern 320 and the surface of the lower insulating interlayer 310 may be substantially coplanar with each other. The second bonding pad pattern 320 may serve as a pad for bonding the first bonding pad pattern 274 formed on the intermediate substrate 116. In some example embodiments, the second bonding pad pattern 320 may include a metal such as tungsten (W), copper (Cu), or aluminum (Al).

The intermediate substrate 116 may include a first semiconductor layer 100a, a silicon oxide layer 102, a second semiconductor layer pattern 110a and a first buried insulation pattern 114. The intermediate substrate 116 may be a silicon on insulator (SOI) substrate having a structure in which the first semiconductor layer 100a, the silicon oxide layer 102, and the second semiconductor layer pattern 110a are stacked, such that the intermediate substrate 116 may be understood to include a stack of the first semiconductor layer 100a, the silicon oxide layer 102, and the second semiconductor layer pattern 110a. The first buried insulation pattern 114 may fill a trench between adjacent second semiconductor layer structures 110ac of the second semiconductor layer pattern 110a. For example, as shown, one or more sidewall surfaces 110as of the second semiconductor layer pattern 110a (e.g., opposing sidewall surfaces 110as of adjacent second semiconductor layer structures 110ac of the second semiconductor layer pattern 110a) may at least partially define a trench 110t extending through the second semiconductor layer pattern 110a (e.g., extending between the adjacent second semiconductor layer structures 110ac which are adjacent in a horizontal direction extending parallel to the lower substrate 300, extending through the trench 110t that extends through the second semiconductor layer pattern 110a in a vertical direction extending perpendicular to the lower substrate 300), and the first buried insulation pattern 114 may fill (e.g., partially or completely fill) the trench 110t (e.g., between the adjacent second semiconductor layer structures 110ac, through the second semiconductor layer pattern 110a, etc.). In some example embodiments, the second semiconductor layer structures 110ac may be separate portions of a single, unitary piece of material that defines the second semiconductor layer pattern 110a. In some example embodiments, the second semiconductor layer structures 110ac may be separate pieces of material, isolated from direct contact with each other, that collectively define the second semiconductor layer pattern 110a. The first semiconductor layer 100a and the second semiconductor layer pattern 110a may be separated from each other (e.g., isolated from direct contact with each other) by the silicon oxide layer 102 to be insulated from each other. A first surface of the first buried insulation pattern 114 positioned on (e.g., located at) a bottom of the trench may contact the silicon oxide layer 102.

In some example embodiments, the first buried insulation pattern 114 may include silicon oxide or silicon nitride.

In some example embodiments, the surface of the second semiconductor layer pattern 110a and the surface of the first buried insulation pattern 114 may be substantially coplanar with each other.

In some example embodiments, the second semiconductor layer pattern 110a may have a thickness of about 1 μm or less. For example, the second semiconductor layer pattern 110a may have a thickness in range of about 0.3 μm to about 1 μm.

A first opening 118 may be included in the first semiconductor layer 100a in the pixel array region, and a first insulation layer 120 may be formed to fill (partially or completely fill) the first opening 118. As shown, the first opening 118 may be at least partially defined by one or more inner surfaces 100as of the first semiconductor layer 100a. The first opening 118 may be disposed to face a position for forming a first through silicon via 256 in each of the pixels PX of the pixel array PA. The first opening 118 may pass through the first semiconductor layer 100a. Thus, the first insulation layer 120 filling the first opening 118 may contact the silicon oxide layer 102. The first insulation layer 120 may cover a surface of the first semiconductor layer 100a.

As shown in FIG. 5, a first impurity region 115 may be formed in a portion of the first semiconductor layer 100a. The first impurity region 115 may be doped with, e.g., P-type impurities of high concentration. The first impurity region 115 may be positioned at a region to which a back bias is to be applied, in the first semiconductor layer 100a. In some example embodiments, the first impurity region 115 may be positioned under a region in which at least one transistor constituting each of pixels formed in the pixel array region.

The second semiconductor layer pattern 110a may serve as an active region of the intermediate substrate 116. The first buried insulation pattern 114 may serve as an isolation region of the intermediate substrate 116.

The intermediate device may be formed on the second semiconductor layer pattern 110a and the first buried insulation pattern 114. The intermediate device may include a plurality of transistors 230T constituting (e.g., at least partially defining and/or each separately included in a separate one of) each of the pixels PX in the pixel array region A. In some example embodiments, each separate pixel PX may be at least partially defined as including at least a separate transistor 230T, a separate photodiode 200, or the like. The lateral boundaries of each pixel X may be at least partially defined by a separate insulating portion of the second insulation layer 210 that may extend through the upper substrate 400 In some example embodiments, the intermediate device may include a selection transistor, a drive transistor, a reset transistor, and a dual conversion gain transistor. Therefore, gates of the transistors may be formed on the second semiconductor layer pattern 110a (on an upper surface of at least one second semiconductor layer pattern 110a) and the first buried insulation pattern 114. Each of the gates may include a gate insulation layer and a gate electrode.

As shown in 4 and 5, a selection gate 230a, a drive gate 230b, and a reset gate 230c and a dual conversion gain gate 230d constituting the transistors 230T may be formed on the second semiconductor layer pattern 110a and the first buried insulation pattern 114.

Second impurity regions (not shown) serving as source/drain may be formed in the second semiconductor layer pattern 110a adjacent to both sides of each of the gates. The second impurity regions may be doped with n-type impurities of high concentration.

A first insulating interlayer 240 may be formed on the second semiconductor layer pattern 110a and the first buried insulation pattern 114 to cover the intermediate device. The first insulating interlayer 240 may include silicon oxide.

A first contact plug 252 may pass (e.g., may extend) through the first insulating interlayer 240, and may contact the drive gate 230b. A second contact plug 254 may pass through the first insulating interlayer 240, the first buried insulation pattern 114, and the silicon oxide layer 102, and may contact the first impurity region 115.

A back bias may be applied to the first impurity region 115 through the second contact plug 254. Thus, noise of the transistor formed on the second semiconductor layer pattern 110a and the first buried insulation pattern 114 may be decreased, during operation of the transistors, thereby improving operational functionality of the image sensor.

Although not shown, contact plugs for electrically connecting to a drive transistor, a reset transistor, and a dual conversion gain transistor constituting the pixel may be further formed in the first insulating interlayer 240.

A second insulating interlayer 260 may be formed on the first insulating interlayer 240. A first connection wiring 262 may be formed in the second insulating interlayer 260. In some example embodiments, the first connection wiring 262 may electrically connect the first through silicon via 256 and at least one of the contact plugs.

A third insulating interlayer 270 may be formed on the second insulating interlayer 260. In addition, a second connection wiring 272 may be formed in the third insulating interlayer 270. A first bonding pad pattern 274 may be formed on the second connection wiring 272. A surface of the first bonding pad pattern 274 may be exposed by a surface of the third insulating interlayer 270. A surface of the first bonding pad pattern 274 and a surface of the third insulating interlayer 270 may be substantially coplanar with each other. In some example embodiments, the first bonding pad pattern 274 may be disposed in the signal processing region B.

The third insulating interlayer 270 on the intermediate substrate 116 and the lower insulating interlayer 310 on the lower substrate 300 may be bonded to each other. The first bonding pad pattern 274 and the second bonding pad pattern 320 may be directly bonded to each other.

The upper substrate 400 may include a silicon substrate, a silicon germanium substrate, or the like.

A photodiode 200, a floating diffusion region 202 and a transfer transistor 204 constituting (e.g., at least partially defining and/or each separately included in a separate one of) each of the pixels PX may be formed at the upper substrate 400 in the pixel array region A. The photodiode 200 may be formed in the upper substrate 400, and the floating diffusion region 202 and the transfer transistor may be formed on a first surface of the upper substrate 400. In addition, a second insulation layer 210 may be formed on the first surface of the upper substrate 400 to cover the transfer transistor 204.

The second insulation layer 210 on the upper substrate 400 and the first insulation layer 120 on the first semiconductor layer 100a in the intermediate substrate 116 may be bonded to each other. The first and second insulation layers 210 and 120 may include silicon oxide. The first and second insulation layers 210 and 120 may be merged into one insulation layer 212.

The first through silicon via 256 may pass through the first insulating interlayer 240, the first buried insulation pattern 114, the silicon oxide layer 102, and the insulation layer 212 positioned in and under the first opening 118. The first through silicon via 256 may extend to the floating diffusion region 202, and may contact the floating diffusion region 202. The first through silicon via 256 may be formed in a pixel array region. In the pixel array region, the intermediate device formed on the intermediate substrate 116 and the floating diffusion region 202 formed on the upper substrate 400 may be electrically connected by the first through silicon via 256.

The first through silicon via 256 may pass through the intermediate substrate 116. As a thickness of the intermediate substrate 116 decreases, a depth of the first through silicon via 256 may decrease. Thus, the first through silicon via 256 may be easily formed. As the depth of the first through silicon via 256 is decreased, a capacitance of the floating diffusion region 202 may be decreased and a conversion gain (CG) may be increased.

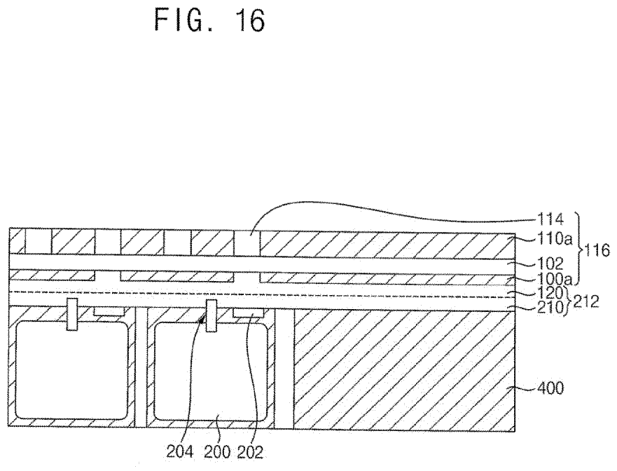

For example, based on the image sensor 1 including an intermediate substrate 116 including a stack of a first semiconductor layer 100a, a silicon oxide layer 102, and a second semiconductor layer pattern 110a each extending in parallel in a horizontal direction parallel to the lower substrate 300, where one or more sidewall surfaces 110as of the second semiconductor layer pattern 110a at least partially define a trench 110t extending through the second semiconductor layer pattern 110a (e.g., in a vertical direction that is perpendicular to the lower substrate 300), and a first buried insulation pattern 114 fills the trench 110t, the first buried insulation pattern 114 may serve as a grinding stop layer during a process for forming the intermediate substrate 116 that includes grinding at least a second surface of a second bare semiconductor substrate 110 until the first buried insulation pattern 114 may be exposed to form (e.g., define) the second semiconductor layer pattern 110a, and the second semiconductor layer pattern 110a may be formed between the first buried insulation pattern 114, for example as shown in at least FIG. 16. Therefore, the grinding process to at least partially form the intermediate substrate 116 may be precisely controlled by using the first buried insulation pattern 114 as the grinding stop layer, thereby enabling the second semiconductor layer pattern 110a to be formed to have a thin thickness (e.g., a reduced thickness in relation to a second semiconductor layer pattern 110a omitting a first buried insulation pattern 114 extending therethrough via trench 110t). In some example embodiments, the second semiconductor layer pattern 110a may thus have a thickness of about 1 μm or less based on being at least partially defined by the first buried insulation pattern 114 during the aforementioned grinding process. For example, the second semiconductor layer pattern 110a may have a thickness in range of about 0.3 μm to about 1 μm. The first semiconductor layer 100a, the silicon oxide layer 102, the second semiconductor layer pattern 110a and the first buried insulation pattern 114 may serve as an intermediate substrate 116 in the image sensor. As the thickness of the second semiconductor layer pattern 110a decreases, a thickness of the intermediate substrate 116 may decrease. Based on the second semiconductor layer pattern 110a having a reduced thickness based on the presence of the first buried insulation pattern 114 to serve as a grinding stop layer during the process for forming the intermediate substrate 116, the thickness of the intermediate substrate 116 may be reduced, thereby enabling a smaller size and improved compactness of the image sensor 1. Additionally, due to the decreased thickness of the intermediate substrate 116, the depth of the first through silicon via 256 may decrease. Thus, the first through silicon via 256 may be more easily formed, thereby reducing manufacturing costs and improving ease of manufacture of the image sensor 1. Additionally, as the depth of the first through silicon via 256 is decreased, a capacitance of the floating diffusion region 202 may be decreased and a conversion gain (CG) may be increased, thereby improving performance and thus functionality of the image sensor 1 based on including the second semiconductor layer pattern 110a having a reduced thickness based on the presence of the first buried insulation pattern 114.

The first connection wiring 262 in the second insulating interlayer 260 may be electrically connected to the first through silicon via 256.

A capping layer 402 may be formed on a second surface opposite to the first surface of the upper substrate 400. The capping layer 402 may include, e.g., silicon oxide.

A second through silicon via 420 may pass through the capping layer 402, the upper substrate 400, the insulation layer 212, the first semiconductor layer 100a, the silicon oxide layer 102, the second semiconductor layer pattern 110a and the first insulating interlayer 240. The second through silicon via 420 may be disposed in the signal processing region except for the pixel array region. The second through silicon via 420 may be electrically connected to the first connection wiring 262. An insulation spacer 412 may be formed on sidewall of the second through silicon via 420, and may surround the second through silicon via 420.

The second through silicon via 420 may pass through the intermediate substrate 116. As a thickness of the intermediate substrate 116 decreases, a depth of the second through silicon via 420 may decrease. Thus, the second through silicon via 420 may be easily formed.

An upper wiring 422 may be formed on the capping layer 402, the insulation spacer 412, and the second through silicon via 420.

Color filters 430 may be formed on the capping layer 402 in the pixel array region. Micro lenses 440 may be formed on the color filters 430. The color filter 430 and the micro lens 440 may include an organic polymer material.

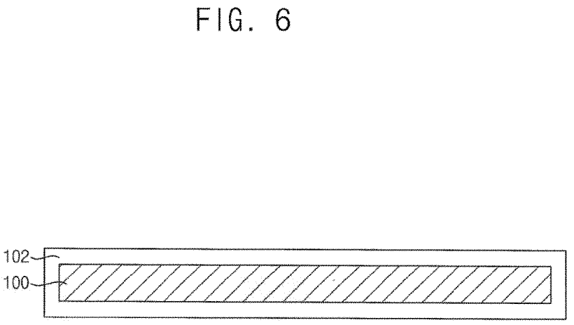

FIGS. 6, 7, 8, 9, 10, 11, 12, 13, 14, 15, 16, 17, 18, 19, 20, 21, and 22 are cross-sectional views illustrating a method of manufacturing an image sensor in accordance with some example embodiments.

1) Fabrication of Initial Intermediate Substrate

Referring to FIG. 6, a silicon oxide layer 102 may be formed on an entire surface of a first bare semiconductor substrate 100. The first bare semiconductor substrate 100 may be a silicon substrate. The silicon oxide layer 102 may be formed by a thermal oxidation process.

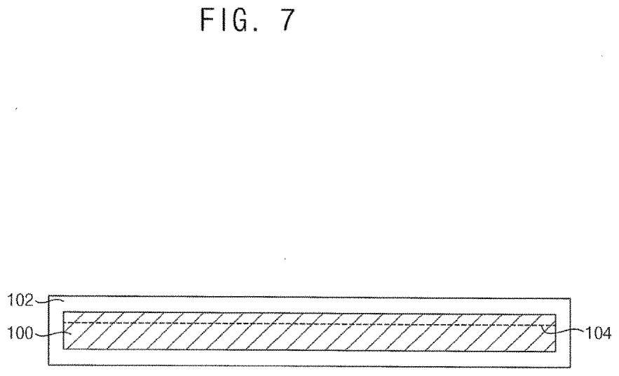

Referring to FIG. 7, hydrogen ions may be implanted into a first surface of the first bare semiconductor substrate 100 through the silicon oxide layer 102. Thus, a hydrogen ion implantation region 104 may be formed in the first bare semiconductor substrate 100. The hydrogen ion implantation region 104 may be positioned at a predetermined depth inward from the first surface of the first bare semiconductor substrate 100.

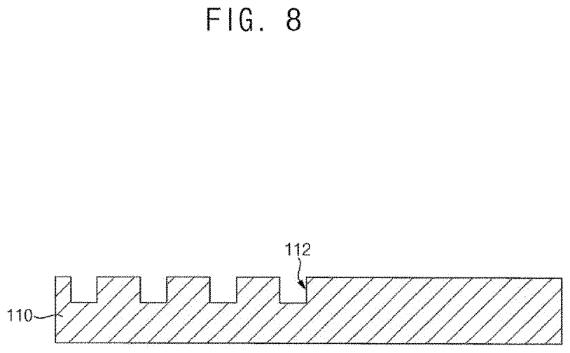

Referring to FIG. 8, first trenches 112 may be formed at a first surface of a second bare semiconductor substrate 110. The second bare semiconductor substrate 110 may be a silicon substrate. In some example embodiments, each of the first trenches 112 may be formed at a region corresponding to an isolation region of the intermediate substrate.

A depth of the first trench 112 may determine a thickness of a second semiconductor layer pattern in an intermediate substrate subsequently formed. The depth of the first trench 112 may be equal to or greater than a target thickness of the second semiconductor layer pattern subsequently formed. In some example embodiments, the depth of the first trench 112 may be equal to the target thickness of the second semiconductor layer pattern subsequently formed.

In some example embodiments, the depth of the first trench 112 may be less than about 1 μm. Particularly, the depth of the first trench 112 may be about 0.3 μm to about 1 μm. When the depth of the first trench 112 is greater than 1 μm, a thickness of the second semiconductor layer pattern may be greater than about 1 μm. Thus, it may be difficult to form first and second through silicon vias. Meanwhile, when the depth of the first trench 112 is less than 0.3 μm, the second semiconductor layer pattern may not have a uniform thickness.

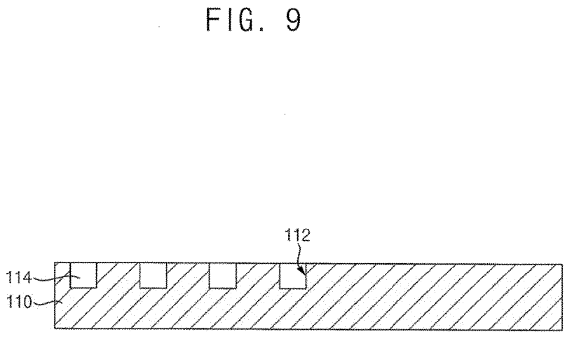

Referring to FIG. 9, a buried insulation layer may be formed on the first surface of the second bare semiconductor substrate 110 to filling the first trench 112. The buried insulation layer may include, e.g., silicon oxide. An upper portion of the buried insulation layer may be planarized until the first surface of the second bare semiconductor substrate 110 may be exposed to form a first buried insulation pattern 114 in the first trench 112. The first buried insulation pattern 114 may include silicon oxide or silicon nitride.

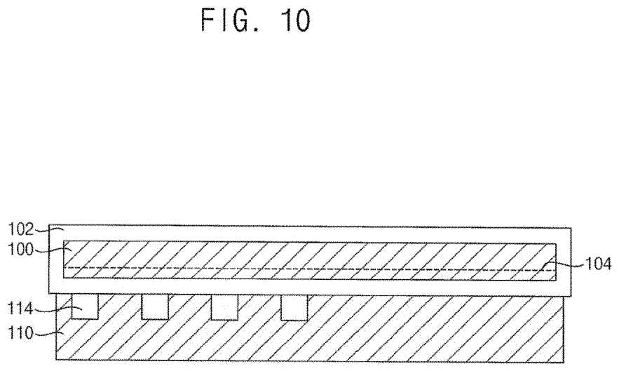

Referring to FIG. 10, the silicon oxide layer 102 and the first buried insulation pattern 114 on the first surface of the first bare semiconductor substrate 100 and the first surface of the second bare semiconductor substrate 110 may be bonded to each other to form a bonded structure.

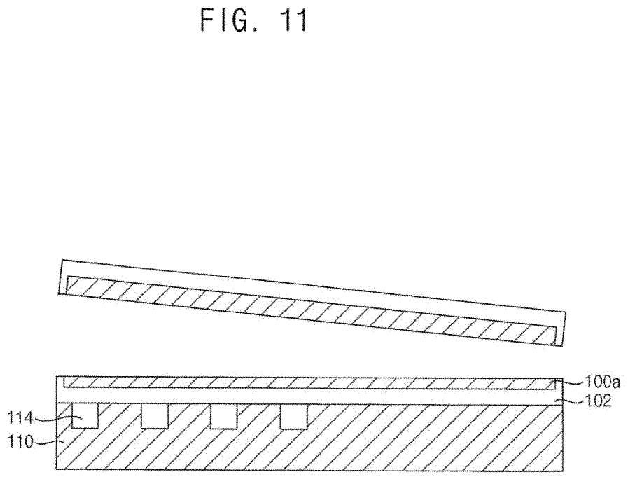

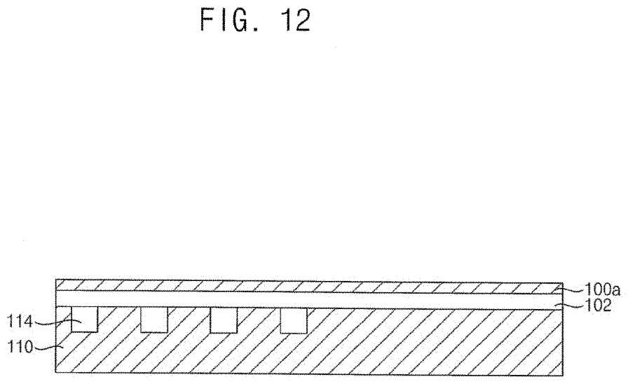

Referring to FIGS. 11 and 12, a portion of the first bare semiconductor substrate 100 may be separated by cutting the hydrogen ion implantation region 104 in the bonded structure.

Therefore, the silicon oxide layer 102 and a first semiconductor layer 100a may be formed on the first surface of the second bare semiconductor substrate 110 and the first buried insulation pattern 114. That is, a remaining first bare semiconductor substrate 100 on the silicon oxide layer 102 after the separation process may serve as the first semiconductor layer 100a.

By performing the above process, a silicon on insulation (SOI) substrate including the second bare semiconductor substrate 110, the first buried insulation pattern 114, the silicon oxide layer 102, and the first semiconductor layer 100a may be formed. The SOI substrate may serve as an initial intermediate substrate.

2) Bonding of Upper Substrate and Intermediate Substrate

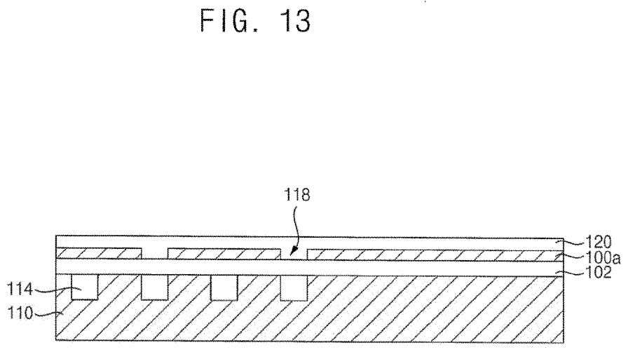

Referring to FIG. 13, in the first semiconductor layer 100a of the SOI substrate, impurities may be doped into a region to which a back bias is to be applied to form first impurity regions (FIG. 5, 115). The first impurity region 115 may be doped with, e.g., P-type impurities of high concentration. In some example embodiments, the region to which the back bias is to be applied may be positioned below a region for forming at least one transistor constituting each of pixels in the pixel array region.

In the first semiconductor layer 100a of the SOI substrate, a portion for forming a first through silicon via may be selectively etched to form a first opening 118.

A first insulation layer 120 may be formed on the first semiconductor layer 100a to fill the first opening 118. The first insulation layer 120 may serve as a bonding layer for bonding an upper substrate and an intermediate substrate. The first insulation layer 120 may include, e.g., silicon oxide. In some example embodiments, a planarization process may further be performed so that an upper surface of the first insulation layer 120 may be flat.

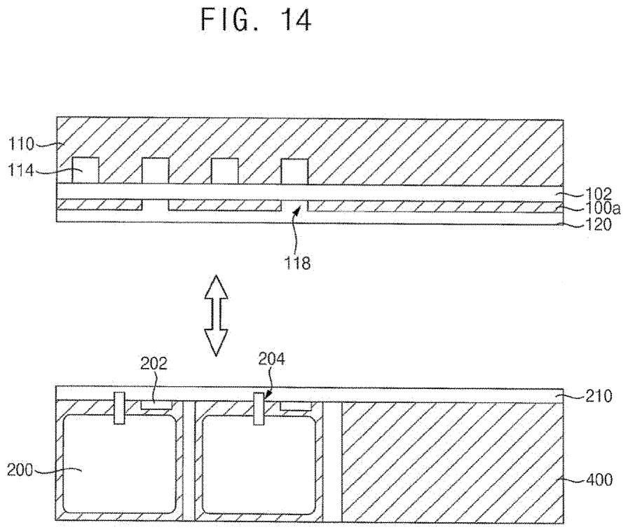

Referring to FIG. 14, a photodiode 200, a floating diffusion region 202 and transfer transistors 204 constituting each of pixels may be formed at an upper substrate 400 in the pixel array region.

A second insulation layer 210 may be formed on a first surface of the upper substrate 400 to cover the photodiode 200, the floating diffusion region 202 and the transfer transistor 204. The second insulation layer 210 may serve as a bonding layer for bonding the upper substrate 400 and the intermediate substrate. The second insulation layer 210 may include, e.g., silicon oxide.

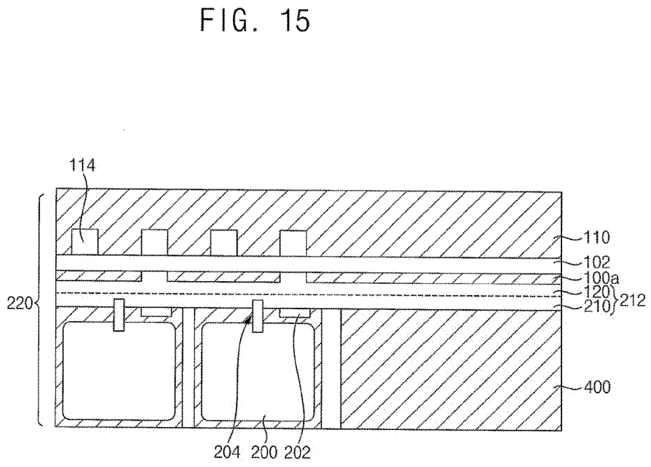

Referring to FIG. 15, the first insulation layer 120 on the SOI substrate and the second insulation layer 210 on the upper substrate 400 may be bonded to each other.

Therefore, a first preliminary bonding structure 220 in which the SOI substrate and the upper substrate 400 are bonded may be formed. The first and second insulation layers 120 and 210 may include the same material, and thus may be merged into one insulation layer 212. A second surface opposite to the first surface of the second bare semiconductor substrate 110 may be exposed.

Referring to FIG. 16, the second surface of the second bare semiconductor substrate 110 may be grinded until the first buried insulation pattern 114 may be exposed to form a second semiconductor layer pattern 110a. The second semiconductor layer pattern 110a may be formed between the first buried insulation pattern 114.

In the grinding process, the first buried insulation pattern 114 may serve as a grinding stop layer. Therefore, the grinding process may be precisely controlled by using the first buried insulation pattern 114 as the grinding stop layer. The second semiconductor layer pattern 110a having a thin thickness may be formed by the grinding process. In some example embodiments, the second semiconductor layer pattern 110a may have a thickness of about 1 μm or less. For example, the second semiconductor layer pattern 110a may have a thickness in range of about 0.3 nm to about 1 μm.

The first semiconductor layer 100a, the silicon oxide layer 102, the second semiconductor layer pattern 110a and the first buried insulation pattern 114 may serve as an intermediate substrate 116 in the image sensor. As the thickness of the second semiconductor layer pattern 110a decreases, a thickness of the intermediate substrate 116 may decrease.

The second semiconductor layer pattern 110a may serve as an active region of the intermediate substrate 116. The first buried insulation pattern 114 may serve as an isolation region of the intermediate substrate 116.

3) Intermediate Device and Wiring

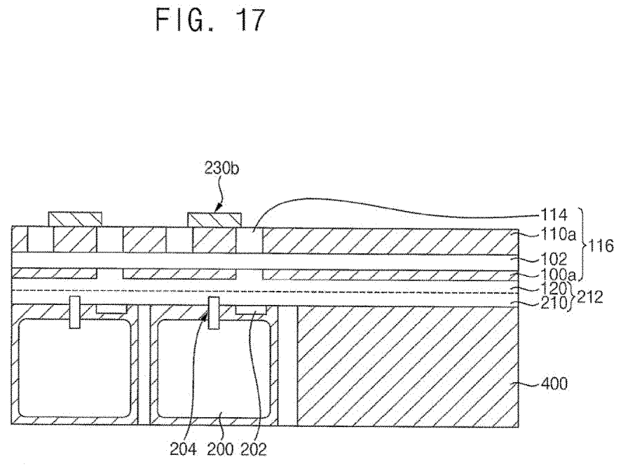

Referring to FIG. 17, an intermediate device may be formed on the second semiconductor layer pattern 110a and the first buried insulation pattern 114. The intermediate device may include a plurality of transistors constituting each of pixels in the pixel array region. In some example embodiments, the intermediate device may include a selection transistor, a drive transistor, a reset transistor, and a dual conversion gain transistor.

As shown in FIG. 4, the selection gate 230a, the drive gate 230b, the reset gate 230c and the dual conversion gain gate 230d of the transistors may be formed on the second semiconductor layer pattern 110a and the first buried insulation pattern 114. In addition, second impurity regions (not shown) serving as source/drain may be formed in the second semiconductor layer pattern 110a adjacent to both sides of each of the gates. The second impurity regions may be doped with n-type impurities of high concentration

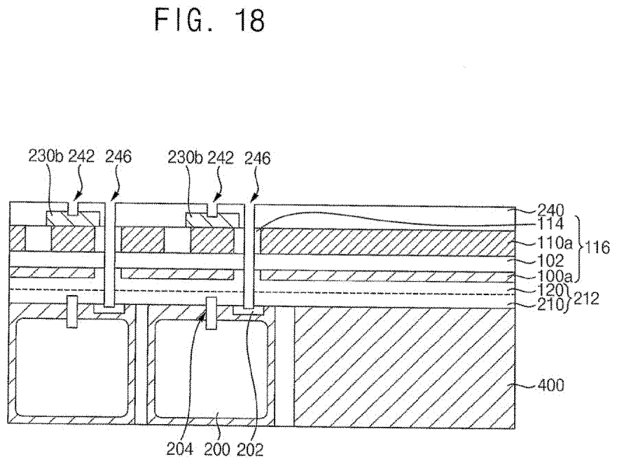

Referring to FIG. 18, a first insulating interlayer 240 may be formed on the second semiconductor layer pattern 110a and the first buried insulation pattern 114 to cover the intermediate device. The first insulating interlayer 240 may include silicon oxide.

A first contact hole 242 may be formed through the first insulating interlayer 240, and the first contact hole 242 may expose the drive gate. A second contact hole (refer to FIG. 4, 244) may be formed through the first insulating interlayer 240, the first buried insulation pattern 114 and the silicon oxide layer 102, and the second contact hole may expose the first impurity region 115 (refer to FIG. 4).

In addition, a first through via hole 246 may be formed through the first insulating interlayer 240, the first buried insulation pattern 114, the silicon oxide layer 102, and the insulation layer 212 positioned in and under the first opening 118. The first through via hole 246 may expose the floating diffusion region 202. The first through via hole 246 may be formed in the pixel array region.

As the thickness of the intermediate substrate 116 including the first semiconductor layer 100a, the silicon oxide layer 102, the second semiconductor layer pattern 110a, and the first buried insulation pattern 114 decreases, a depth of the first through via hole 246 passing through the intermediate substrate 116 may decrease. Thus, an etching process for forming the first through via hole 246 may be easily performed.

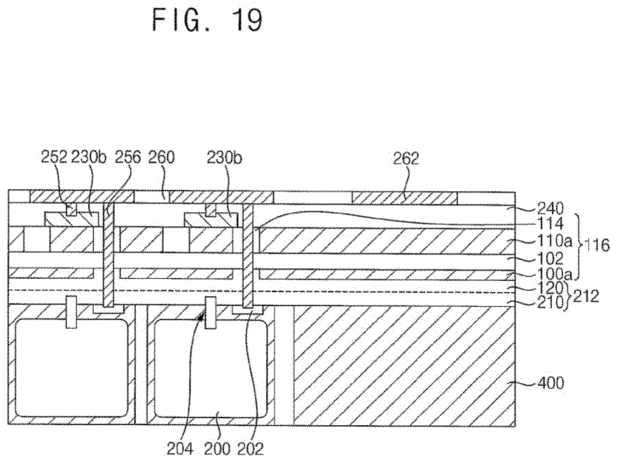

Referring to FIG. 19, a conductive material may be formed to fill the first contact hole 242, the second contact hole 244 and the first through via hole 246. The conductive material may be planarized to form a first contact plug 252, a second contact plug 254 (refer to FIG. 4) and a first through silicon via 256 filling the first contact hole 242, the second contact hole 244 and the first through via hole 246, respectively.

Meanwhile, although not shown, contact plugs electrically connected to a drive transistor, a reset transistor, and a dual conversion gain transistor constituting the pixel may be further formed in the first insulating interlayer 240.

A second insulating interlayer 260 may be formed on the first insulating interlayer 240.

A first connection wiring 262 may be formed through the second insulating interlayer 260, and the first connection wiring 262 may be connected to each of the first contact plug 252, the second contact plug 254 and the first through silicon via 256.

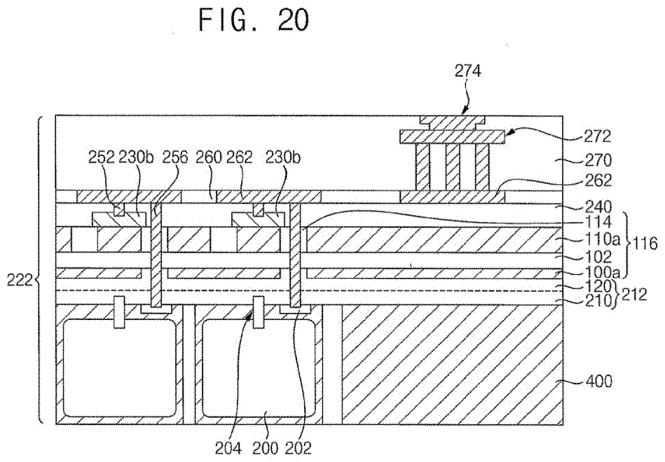

Referring to FIG. 20, a third insulating interlayer 270 may be formed on the second insulating interlayer 260, the contact plugs 252 and 254, and the first connection wiring 262. In addition, a second connection wiring 272 may be formed in the third insulating interlayer 270. A first bonding pad pattern 274 may be formed on the second connection wiring 272. In some example embodiments, the first bonding pad pattern 274 may be disposed in the signal processing region.

An upper surface of the first bonding pad pattern 274 and an upper surface of the third insulating interlayer 270 may be coplanar with each other.

By performing the above processes, a second preliminary bonding structure 222 in which the intermediate substrate 116 and the upper substrate 400 are bonded may be formed.

4) Bonding of Lower Substrate

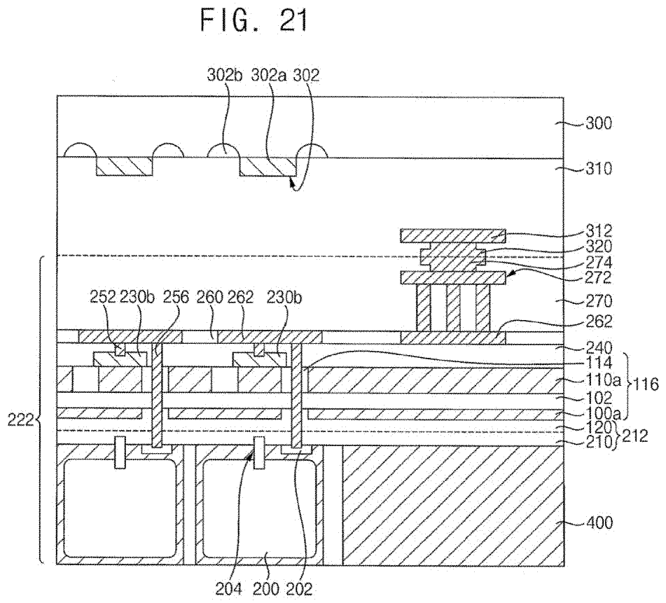

Referring to FIG. 21, a logic transistor 302 and wiring (not shown) constituting a logic circuit may be formed on a lower substrate 300. The logic transistor 302 may include a lower gate 302a and a lower impurity region 302b.

A lower insulating interlayer 310 may be formed on the lower substrate 300 to cover the logic transistor 302 and wiring. The lower insulating interlayer 310 may include, e.g., silicon oxide.

A third connection wiring 312 may be formed in the lower insulating interlayer 310. A second bonding pad pattern 320 may be formed on the third connection wiring 312. In some example embodiments, the second bonding pad pattern 320 may be disposed in the signal processing region except for the pixel array region.

A surface of the second bonding pad pattern 320 and a surface of the lower insulating interlayer 310 may be coplanar with each other.

The third insulating interlayer 270 of the second preliminary bonding structure 222 and the lower insulating interlayer 310 on the lower substrate 300 may be bonded to each other. In the bonding process, the first bonding pad pattern 274 and the second bonding pad pattern 320 may be directly bonded to each other.

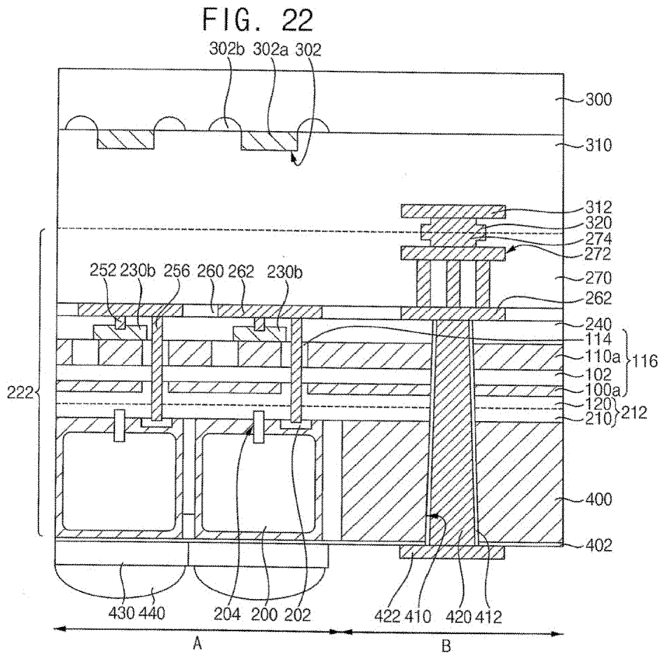

Referring to FIG. 22, a second surface of the upper substrate 400 may be grinded so that a thickness of the upper substrate 400 may be thin. A capping layer 402 may be formed on the second surface of the upper substrate 400. The capping layer 402 may include, e.g., silicon oxide.

A second through via hole 410 may be formed through the capping layer 402, the upper substrate, the insulation layer 212, the first semiconductor layer 100a, the silicon oxide layer 102, the second semiconductor layer pattern 110a and the first insulating interlayer 240. The second through via hole 410 may be disposed in the signal processing region except for the pixel array region. The second through via hole 410 may expose the first connection wiring 262. The second through via hole 410 may pass through the intermediate substrate 116. As the thickness of the intermediate substrate 116 decreases, the second through via hole 410 may be easily formed.

An insulation spacer 412 may be formed on a sidewall of the second through via hole 410. A conductive material may be formed to fill the second through via hole 410, and the conductive material may be planarized to form second through silicon via 420 filling the second through via hole 410.

Thereafter, an upper wiring 422 may be formed on the capping layer 402, the insulation spacer 412 and the second through silicon via 420.

Color filters 430 may be formed on the capping layer 402 in the pixel array region. Micro lenses 440 may be formed on the color filters 430.

An image sensor may be manufactured by the above process.

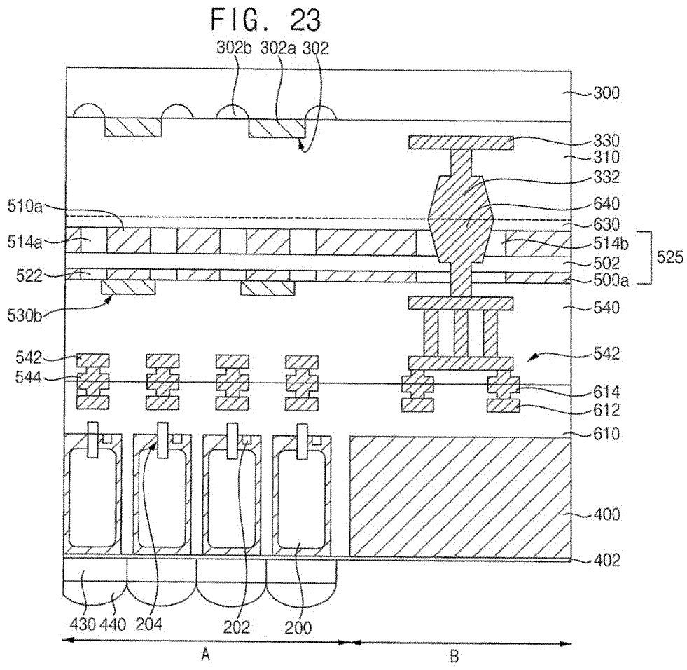

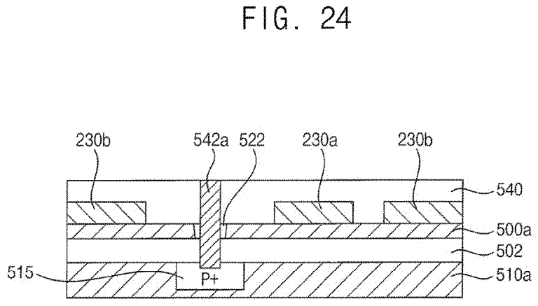

FIG. 23 is a cross-sectional view illustrating image sensors in accordance with some example embodiments. FIG. 24 is a cross-sectional view illustrating a portion of an intermediate device formed on an intermediate substrate in the image sensor in accordance with some example embodiments.

Referring to FIG. 23, the image sensor may include a lower device formed on a lower substrate 300, an intermediate device formed on an intermediate substrate 525, and an upper device formed on an upper substrate 400. The image sensor may have a structure in which the lower substrate 300, the intermediate substrate 525, and the upper substrate 400 may be bonded. In FIG. 23, the lower substrate 300 may be positioned at an uppermost portion and the upper substrate 400 may be positioned at a lowermost portion.

The lower substrate 300 may include a silicon substrate, a silicon germanium substrate, or the like.

The lower device may include logic transistors 302 and wiring (not shown) constituting a logic circuit. Particularly, the lower device may include a lower impurity region 302b formed in the lower substrate 300 and a lower gate 302a formed on the lower substrate 300.

A lower insulating interlayer 310 may be formed on the lower substrate 300 to cover the lower gate 302a. The lower insulating interlayer 310 may include silicon oxide.

A lower connection wiring 330 may be formed in the lower insulating interlayer 310. In some example embodiments, the lower connection wiring 330 may be formed in multiple layers.

A via contact 332 may be disposed on the lower connection wiring 330. In some example embodiments, the via contact 332 may be disposed in the signal processing regions. An upper surface of the via contact 332 and an upper surface of the lower insulating interlayer 310 may be coplanar with each other. The via contact 332 may serve as a bonding pad for bonding a through silicon via formed in the intermediate substrate 525.

The intermediate substrate 525 may include a first semiconductor layer 500a, an isolation pattern 522, a silicon oxide layer 502, a second semiconductor layer pattern 510a, and first and second buried insulation patterns 514a and 514b. The intermediate substrate 525 may have a structure in which the first semiconductor layer 500a, the silicon oxide layer 502, and the second semiconductor layer pattern 510a are stacked. The first semiconductor layer 500a and the second semiconductor layer pattern 510a may be separated from each other by the silicon oxide layer 502. Thus, the first semiconductor layer 500a and the second semiconductor layer pattern 510a may be insulated from each other.

The isolation pattern 522 may pass through the first semiconductor layer 500a, and may contact the silicon oxide layer 502.

A first buried insulation pattern 514a and a second buried insulation pattern 514b may be formed in a trench between the second semiconductor layer patterns 510a. The first and second buried insulation patterns 514a and 514b may contact the silicon oxide layer 502. The first and second buried insulation patterns 514a and 514b may include silicon oxide or silicon nitride.

The first buried insulation pattern 514a may be disposed in a pixel array region. The second buried insulation pattern 514b may be disposed in the signal processing region. The first buried insulation pattern 514a may have a first width, and the second buried insulation pattern 514b may have a second width greater than the first width. The isolation pattern 522 may include silicon oxide.

In some example embodiments, all of the first and second buried insulation patterns 514a and 514b, the silicon oxide layer 502 and the isolation pattern 522 may include silicon oxide. In this case, the first and second buried insulation patterns 514a and 514b, the silicon oxide layer 502 and the isolation pattern 522 may be connected to each other.

The second semiconductor layer pattern 510a may have a thickness less than about 1 μm. For example, the thickness of the second semiconductor layer pattern 510a may be about 0.3 μm to about 1 μm. As the thickness of the second semiconductor layer pattern 510a decreases, the thickness of the intermediate substrate 525 may decrease.

The first semiconductor layer 500a may serve as an active region of the intermediate substrate 525. The isolation pattern 522 may serve as an isolation region of the intermediate substrate 525.

Referring to FIG. 24, a first impurity region 515 may be formed in a portion of the second semiconductor layer pattern 510a. The first impurity region 515 may be doped with, e.g., P-type impurities of high concentration. The first impurity region 515 may be disposed at a region to which a back bias is to be applied, in the second semiconductor layer pattern 510a. In some example embodiments, the first impurity region 515 may be disposed under a region for forming at least one transistor constituting each of pixels in the pixel array region.

An intermediate device may be formed on the first semiconductor layer 500a and the isolation pattern 522. The intermediate device may include a plurality of transistors constituting each of pixels in the pixel array region. In some example embodiments, the intermediate device may include the selection transistor, the drive transistor, the reset transistor and the dual conversion gain transistor.

As shown in FIG. 24, the selection gate 230a, the drive gate 230b, the reset gate 230c, and the dual conversion gain gate 230d may be formed on the first semiconductor layer 500a and the isolation pattern 522. Second impurity regions (not shown) serving as source/drain may be formed in the first semiconductor layer 500a adjacent to both sides of each of the gate electrodes. The second impurity regions may be doped with n-type impurities of high concentration.

A first insulating interlayer 540 may be formed on the first semiconductor layer 500a and the isolation pattern 522 to cover the intermediate device. The first insulating interlayer 540 may include silicon oxide.

A first wiring 542 electrically connected to the selection transistor, the drive transistor, the reset transistor, and the dual conversion gain transistor may be formed in the first insulating interlayer 540. The first wiring 542 may include a contact plug electrically connected to the first impurity region 515, and the contact plug may pass through the isolation pattern 522, the silicon oxide layer 502 and the first insulating interlayer 540. The first wiring 542 may be formed in the pixel array region A and the signal processing region B.

A first bonding pad pattern 544 electrically connected to the first wiring 542 may be formed in the first insulating interlayer 540. An upper surface of the first bonding pad pattern 544 and an upper surface of the first insulating interlayer 540 may be coplanar with each other.

An upper oxide layer 630 may be formed on the second semiconductor layer pattern 510a and the first and second buried insulation patterns 514a and 514b.

A through silicon via 640 may pass through the upper oxide layer 630, the second buried insulation pattern 514b, the silicon oxide layer 502 and the isolation pattern 522, and the through silicon via 640 may be electrically connected to the first wiring 542. The through silicon via 640 may be formed in the signal processing region. An upper surface of the through silicon via 640 and an upper surface of the upper oxide layer 630 may be coplanar with each other.

The through silicon via 640 may pass through the intermediate substrate 525. As a thickness of the intermediate substrate 525 is decreased, the through silicon via 640 may be more easily formed.

The upper oxide layer 630 on the intermediate substrate 525 and the lower insulating interlayer 310 on the lower substrate 300 may be bonded to each other. The through silicon via 640 and the via contact 332 may be directly bonded to each other.

The upper substrate 400 may include a silicon substrate, a silicon germanium substrate, or the like.

The upper device may include a photodiode 200, a floating diffusion region 202 and a transfer transistor 204 constituting each of pixels.

A second insulating interlayer 610 may be formed on the first surface of the upper substrate 400 to cover the photodiode 200, the floating diffusion region 202, and the transfer transistor 204.

A second wiring 612 electrically connected to the photodiode 200, the floating diffusion region 202, and the transfer transistor 204 may be formed in the second insulating interlayer 610. The second wiring 612 may be formed in the pixel array region and the signal processing region.

A second bonding pad pattern 614 electrically connected to the second wiring 612 may be formed in the second insulating interlayer 610. An upper surface of the second bonding pad pattern 614 and an upper surface of the second insulating interlayer 610 may be coplanar with each other.

The first insulating interlayer 540 on the intermediate substrate 525 and the second insulating interlayer 610 on the upper substrate 400 may be bonded to each other. The first bonding pad pattern 544 and the second bonding pad pattern 614 may be directly bonded to each other.

The first and second bonding pad patterns 544 and 614 may be formed in the pixel array region and the signal processing region. As the first and second bonding pad patterns 544 and 614 are bonded, the intermediate device formed on the intermediate substrate 525 and the upper device formed on the upper substrate 400 may be electrically connected to each other.

A capping layer 402 may be formed on a second surface opposite to the first surface of the upper substrate 400. The capping layer 402 may include, e.g., silicon oxide.

Color filters 430 may be formed on the capping layer 402 in the pixel array region. Micro lenses 440 may be formed on the color filters 430.

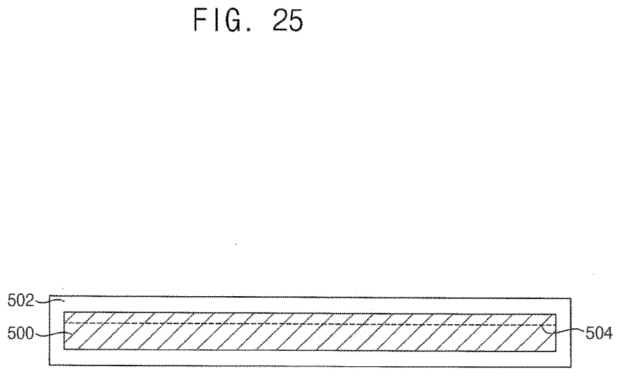

FIGS. 25, 26, 27, 28, 29, 30, 31, 32, 33, 34, 35, 36, and 37 are cross-sectional views illustrating a method of manufacturing an image sensor in accordance with some example embodiments.

1) Initial Intermediate Substrate Fabrication

Referring to FIG. 25, a silicon oxide layer 502 may be formed on an entire surface of a first bare semiconductor substrate 500. The silicon oxide layer 502 may be formed by a thermal oxidation process.

Hydrogen ions may be implanted into a first surface of the first bare semiconductor substrate 500 through the silicon oxide layer 502. Thus, a hydrogen ion implantation region 504 may be formed in the first bare semiconductor substrate 500. The hydrogen ion implantation region 504 may be positioned at a predetermined depth inward from the first surface of the first bare semiconductor substrate 500.

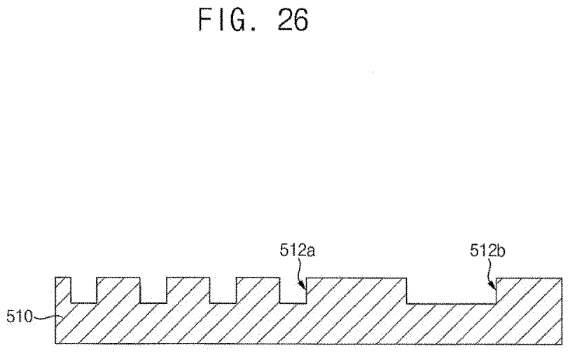

Referring to FIG. 26, a first trench 512a and a second trench 512b may be formed at the first surface of the second bare semiconductor substrate 510.

The first trench 512a may be formed in the pixel array region. The second trench 512b may be formed in the signal processing region. In some example embodiments, a width of the second trench 512b may be greater than a width of the first trench 512a.

In some example embodiments, the first trench 512a may be disposed to face at least a portion of isolation patterns formed in the intermediate substrate. However, a position and a shape of the first trench 512a may not be limited thereto, and the position or the shape may be changed.

The second trench 512b may be disposed at a region for forming a through silicon via in a subsequent process.

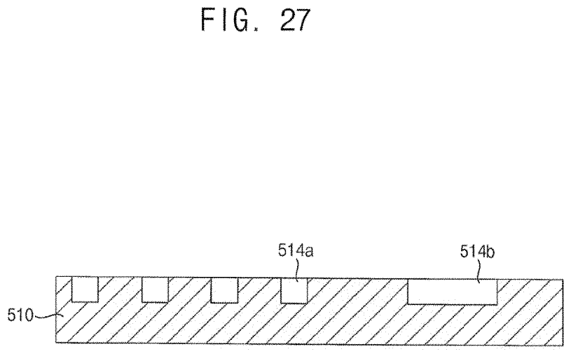

Referring to FIG. 27, a buried insulation layer may be formed on the first surface of the second bare semiconductor substrate 510 to fill the first and second trenches 512a and 512b. The buried insulation layer may include silicon oxide. An upper portion of the buried insulation layer may be planarized until the first surface of the second bare semiconductor substrate 510 may be exposed to form a first buried insulation pattern 514a filling the first trench 512a and a second buried insulation pattern 514b filling the second trench 512b.

Depths of the first and second trenches 512a and 512b may determine a thickness of the second semiconductor layer pattern in the intermediate substrate subsequently formed. In some example embodiments, the depth of each of the first and second trenches 512a and 512b may be less than about 1 μm. For example, each of the first and second trenches 512a and 512b may have a depth of about 0.3 μm to about 1 μm. When the depths of the first and second trenches 512a and 512b are greater than 1 μm, a thickness of the second semiconductor layer pattern may be greater than 1 μm. Therefore, it may be difficult to form a through via contact. Meanwhile, when the depths of the first and second trenches 512a and 512b are less than about 0.3 μm, the second semiconductor layer may not have a uniform thickness.

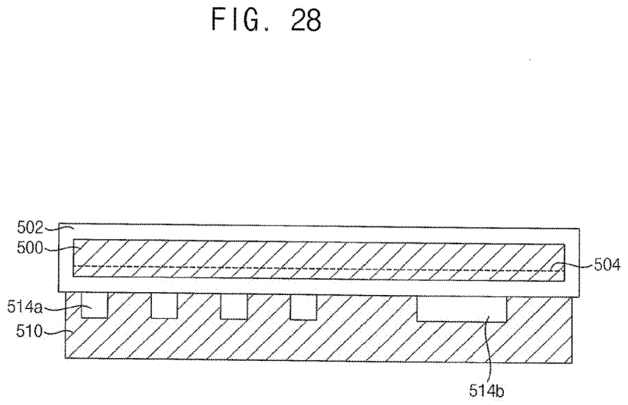

Referring to FIG. 28, the silicon oxide layer 502 and the first and second buried insulation patterns 514a and 514b on the first surface of the first bare semiconductor substrate 500 and a first surface of the second bare semiconductor substrate 510 may bonded to each other to form a bonded structure.

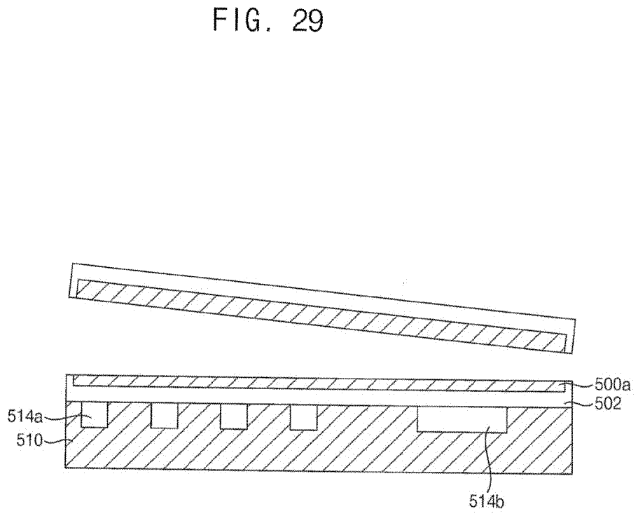

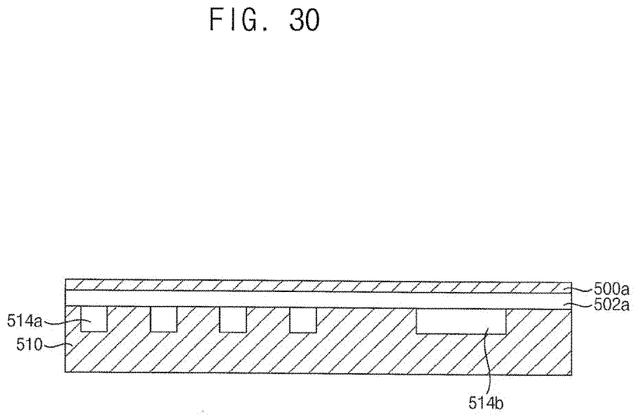

Referring to FIGS. 29 and 30, a portion of the first bare semiconductor substrate 500 may be separated by cutting the hydrogen ion implantation region 504 in the bonded structure.

Thus, a silicon oxide layer 502 and a first semiconductor layer 500a may be formed on the first surface of the second bare semiconductor substrate 510 and the first and second buried insulation patterns 514a and 514b.

By performing the above process, a SOI (silicon on insulation) substrate including the second bare semiconductor substrate 510, the first buried insulation pattern 514a, the second buried insulation pattern 514b, the silicon oxide layer 502 and the first semiconductor layer 500a may be formed. The SOI substrate may serve as an initial intermediate substrate.

2) Forming of Intermediate Device and Wiring

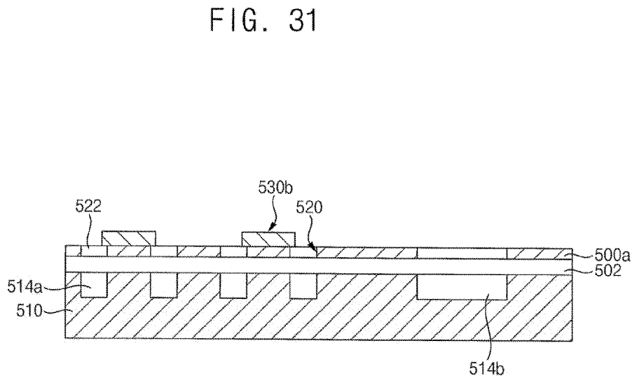

Referring to FIG. 31, a portion of the first semiconductor layer 500a may be etched to form a third trench 520. The third trench 520 may be formed at a portion corresponding to an isolation region of the intermediate substrate. The silicon oxide layer 502 may be exposed by a bottom of the third trench 520.

An insulation layer may be formed on the first semiconductor layer 500a to fill the third trench 520. The insulation layer may include, e.g., silicon oxide. An upper portion of the insulation layer may be planarized until the first semiconductor layer 500a may be exposed to form an isolation pattern 522 in the third trench 520.

An intermediate device may be formed on the first semiconductor layer 500a and the isolation pattern 522. The intermediate device may include a plurality of transistors constituting each of pixels in the pixel array region. In some example embodiments, the intermediate device may include the selection transistor, the drive transistor, the reset transistor, the dual conversion gain transistor, or the like.

That is, the selection gate, the drive gate 530b, the reset gate, and the dual conversion gain gate constituting the transistors may be formed on the first semiconductor layer 500a and the isolation pattern 522. In addition, second impurity regions (not shown) serving as source/drain may be formed in the first semiconductor layer 500a adjacent to both sides of each of the gate electrodes. The second impurity regions may be doped with n-type impurities of high concentration

As shown in FIG. 24, in the SOI substrate, a portion of the second bare semiconductor substrate 510 immediately below the silicon oxide layer 502 may be doped with impurities to form the first impurity region 515. The first impurity region 515 may be positioned at a region to which a back bias is to be applied. The first impurity region 515 may be doped with, e.g., P-type impurities of high concentration.

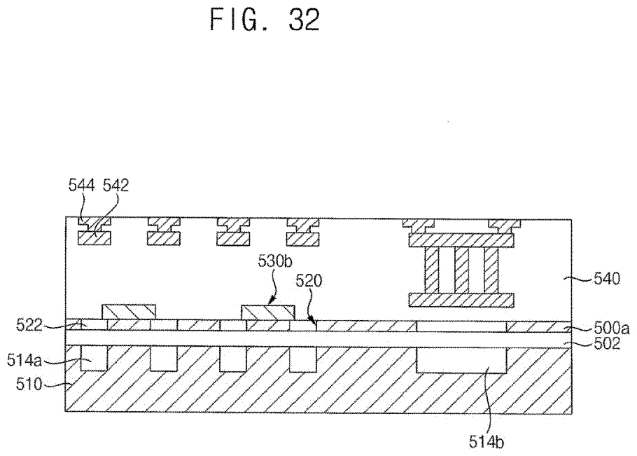

Referring to FIG. 32, a first insulating interlayer 540 may be formed on the first semiconductor layer 500a and the isolation pattern 522 to cover the intermediate device. The first insulating interlayer 540 may include silicon oxide.

A first wiring 542 electrically connected to the selection transistor, the drive transistor, the reset transistor and the dual conversion gain transistor may be formed in the first insulating interlayer 540. The first wiring 542 may include a contact plug (FIG. 24, 542a) passing through the isolation pattern 522, the silicon oxide layer 502 and the first insulating interlayer 540. The contact plug may be electrically connected to the first impurity region (FIG. 24, 515). The first wiring 542 may be formed in the pixel array region and the signal processing region.

A first bonding pad pattern 544 electrically connected to the first wiring 542 may be formed in the first insulating interlayer 540. An upper surface of the first bonding pad pattern 544 and an upper surface of the first insulating interlayer 540 may be coplanar with each other.

3) Bonding of Upper Substrate and Intermediate Substrate

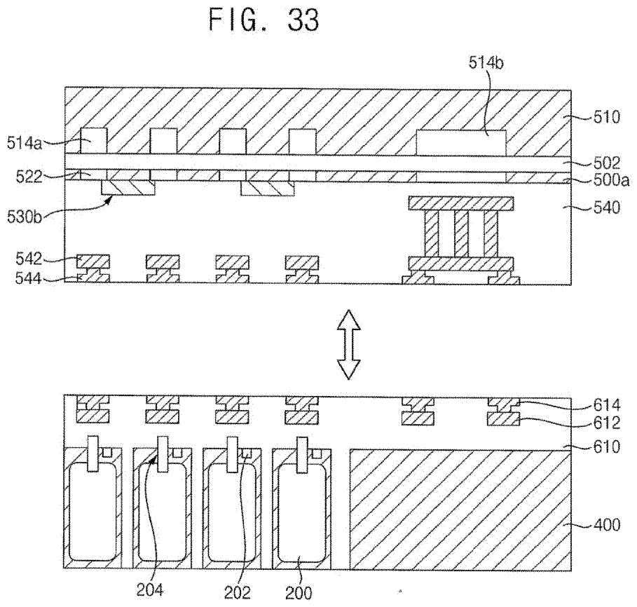

Referring to FIG. 33, the photodiode 200, the floating diffusion region 202, and the transfer transistor 204 constituting each of pixels may be formed at the upper substrate 400 in the pixel array region.

A second insulating interlayer 610 may be formed on the first surface of the upper substrate 400 to cover the photodiode 200, the floating diffusion region 202 and the transfer transistor 204.

A second wiring 612 electrically connected to the photodiode 200, the floating diffusion region 202 and the transfer transistor 204 may be formed in the second insulating interlayer 610. Also, the second wiring 612 may be formed in the pixel array region and the signal processing region.

A second bonding pad pattern 614 electrically connected to the second wiring 612 may be formed in the second insulating interlayer 610. An upper surface of the second bonding pad pattern 614 and an upper surface of the second insulating interlayer 610 may be coplanar with each other.

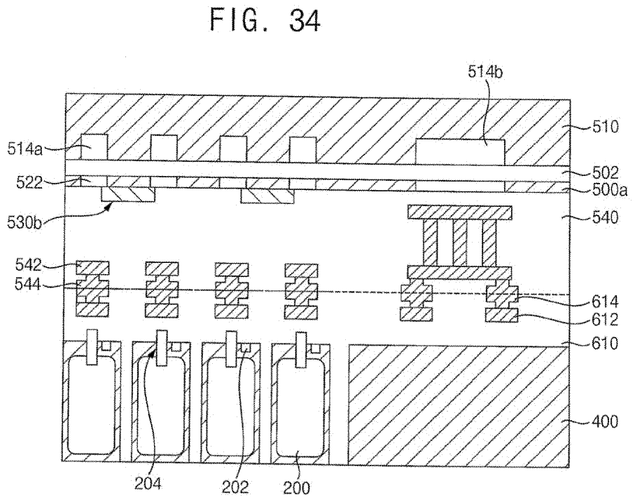

Referring to FIG. 34, the first insulating interlayer 540 on the initial intermediate substrate and the second insulating interlayer 610 on the upper substrate 400 may be bonded to each other. In the bonding process, the first bonding pad pattern 544 and the second bonding pad pattern 614 may be directly bonded to each other.

Therefore, in the pixel array region, the intermediate device formed on the initial intermediate substrate and the upper device formed on the upper substrate may be electrically connected to each other by bonding the first and second bonding pad patterns 544 and 614.

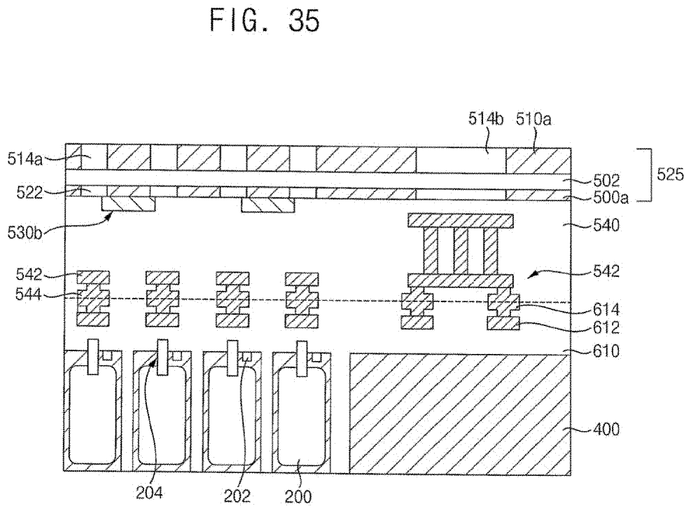

Referring to FIG. 35, a second surface opposite to the first surface of the second bare semiconductor substrate 510 may be ground until the first and second buried insulation patterns 514a and 514b may be exposed to form a second semiconductor layer pattern 510a. The first and second buried insulation patterns 514a and 514b may be disposed between the second semiconductor layer patterns 510a.

In this case, the grinding process may be precisely controlled by using the first and second buried insulation patterns 514a and 514b as a grinding stop layer. Thus, the second semiconductor layer pattern 510a may be formed to have thin thickness. In some example embodiments, the second semiconductor layer pattern 510a may have a thickness of about 1 μm or less. For example, the second semiconductor layer pattern 510a may have a thickness within a range of about 0.3 μm to about 1 μm.

Therefore, the intermediate substrate 525 including the first semiconductor layer 500a, the isolation pattern 522, the silicon oxide layer 502, the second semiconductor layer pattern 510a and the first and second buried insulation patterns 514a and 514b may be formed. As the thickness of the second semiconductor layer pattern 510a decreases, a thickness of the intermediate substrate 525 may decrease.

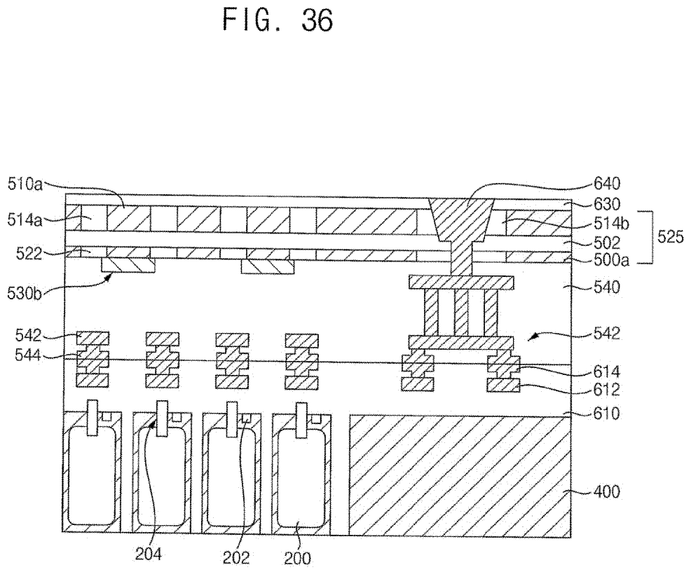

Referring to FIG. 36, an upper oxide layer 630 may be formed on the second semiconductor layer pattern 510a and the first and second buried insulation patterns 514a and 514b. The upper oxide layer 630 may serve as a bonding layer. The upper oxide layer 630 may include silicon oxide.

A through via hole may be formed through the upper oxide layer 630, the second buried insulation pattern 514b, the silicon oxide layer 502 and the isolation pattern 522, and may expose the first wiring 542. After filling a conductive material in the through via hole, the conductive material may be planarized to expose the upper oxide layer 630. Thus, a through silicon via 640 may be formed through the upper oxide layer 630, the second buried insulation pattern 514b, the silicon oxide layer 502 and the isolation pattern 522, and the through silicon via 640 may be electrically connected to the first wiring 542. The through silicon via 640 may be formed in the signal processing region. An upper surface of the through silicon via 640 and an upper surface of the upper oxide layer 630 may be coplanar with each other.

The through silicon via 640 may be formed through the intermediate substrate 525. Therefore, as the thickness of the intermediate substrate 525 decreases, a depth of the through silicon via 640 may decrease. Therefore, the through silicon via 640 may be easily formed.

4) Bonding of Lower Substrate

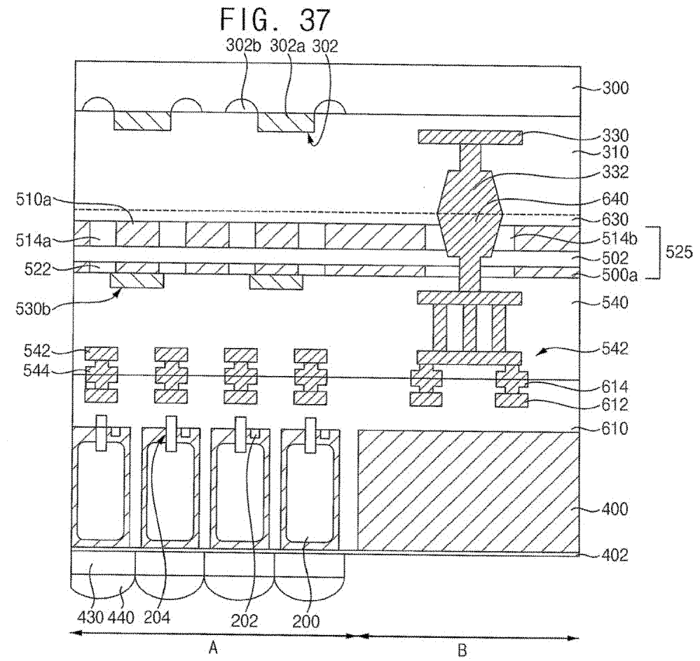

Referring to FIG. 37, a logic transistor 302 and wiring (not shown) constituting a logic circuit may be formed on the lower substrate 300. The logic transistor 302 may include a lower gate 302a and a lower impurity region 302b.

A lower insulating interlayer 310 may be formed on the lower substrate 300 to covering the logic transistor 302 and wiring. The lower insulating interlayer 310 may include, e.g., silicon oxide.

A lower connection wiring 330 may be formed in the lower insulating interlayer 310. A via contact 332 may be formed on the lower connection wiring 330. In some example embodiments, the via contact 332 may be disposed in signal processing regions.

An upper surface of the via contact 332 and an upper surface of the lower insulating interlayer 310 may be coplanar with each other.

The upper oxide layer 630 on the intermediate substrate 525 and the lower insulating interlayer 310 on the lower substrate 300 may be bonded to each other. In the bonding process, the through silicon via 640 and the via contact 332 may be directly bonded to each other.

Thereafter, the second surface of the upper substrate 400 may be grinded to reduce a thickness of the upper substrate 400. A capping layer 402 may be formed on the second surface of the upper substrate 400. The capping layer 402 may include, e.g., silicon oxide.

Color filters 430 may be formed on the capping layer 402 in the pixel array region. Micro lenses 440 may be formed on the color filters 430.

An image sensor may be manufactured by the above process.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concepts. Accordingly, all such modifications are intended to be included within the scope of the present inventive concepts as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. An image sensor, comprising:
a lower device on a lower substrate, the lower device including a logic transistor;
an intermediate device on an intermediate substrate on the lower substrate, the intermediate device including at least one transistor; and
an upper device on an upper substrate on the intermediate substrate, the upper device including a photodiode and a floating diffusion region,
wherein the lower substrate, the intermediate substrate and the upper substrate are stacked,
wherein the intermediate substrate includes a stack of a first semiconductor layer, a silicon oxide layer, and a second semiconductor layer pattern,
wherein the first semiconductor layer includes one or more inner surfaces at least partially defining an opening in the first semiconductor layer, and an insulation pattern fills the opening, and
wherein at least one sidewall surface of the second semiconductor layer pattern at least partially defines a trench extending through the second semiconductor layer pattern, and a buried insulation pattern fills the trench extending through the second semiconductor layer pattern.

2. The image sensor of claim 1, wherein the buried insulation pattern includes silicon oxide or silicon nitride.

3. The image sensor of claim 1, wherein a first surface of the buried insulation pattern at a bottom of the trench contacts the silicon oxide layer.

4. The image sensor of claim 1, wherein a surface of the second semiconductor layer pattern and a surface of the buried insulation pattern are coplanar with each other.

5. The image sensor of claim 1, wherein a gate of the transistor is on an upper surface of the second semiconductor layer pattern.

6. The image sensor of claim 5, further comprising a first through silicon via electrically connected to the transistor on the intermediate substrate,
wherein the first through silicon via extends through the buried insulation pattern, the silicon oxide layer, and the insulation pattern in the opening, and the first through silicon via extends to the floating diffusion region of the upper substrate from the intermediate substrate.

7. The image sensor of claim 5, wherein the image sensor includes a pixel array region and a signal processing region, and the image sensor includes a second through silicon via extending through the upper substrate and the intermediate substrate, the second through silicon via located in the signal processing region.

8. The image sensor of claim 5, further comprising a contact plug extending through the buried insulation pattern and the silicon oxide layer from the intermediate substrate, the contact plug contacting a surface of the first semiconductor layer.

9. The image sensor of claim 1, wherein the second semiconductor layer pattern has a thickness in a range of 0.3 μm to 1 μm.

10. The image sensor of claim 1, wherein a gate of the transistor is on an upper surface of the first semiconductor layer.

11. The image sensor of claim 10, further comprising:
a first insulating interlayer covering the intermediate device;
a first bonding pad pattern in the first insulating interlayer, an upper surface of the first bonding pad pattern exposed by a surface of the first insulating interlayer;
a second insulating interlayer covering the upper device; and
a second bonding pad pattern in the second insulating interlayer, an upper surface of the second bonding pad pattern exposed by a surface of the second insulating interlayer,
wherein the first bonding pad pattern and the second bonding pad pattern are bonded to each other.

12. The image sensor of claim 10, wherein the image sensor includes a pixel array region and a signal processing region, and the image sensor includes a second through silicon via extending through the intermediate substrate, the second through silicon via located in the signal processing region.

13. An image sensor, comprising:
a lower device on a lower substrate, the lower device including a logic transistor;
a first insulating interlayer covering the lower device;
an intermediate device on a first surface of an intermediate substrate on the lower substrate, the intermediate device including at least one transistor;
a second insulating interlayer covering the intermediate device;
an upper device on an upper substrate on the intermediate substrate, the upper device including a photodiode and a floating diffusion region; and
a third insulating interlayer covering the upper device,
wherein a surface of the first insulating interlayer and a surface of the second insulating interlayer are bonded to each other,
wherein a second surface opposite to the first surface of the intermediate substrate and a surface of the third insulating interlayer are bonded to each other,
wherein the intermediate substrate includes a stack of a first semiconductor layer, a silicon oxide layer, and a second semiconductor layer pattern, and
wherein at least one sidewall surface of the second semiconductor layer pattern at least partially defines a trench extending through the second semiconductor layer pattern, and a buried insulation pattern fills the trench extending through the second semiconductor layer pattern.

14. The image sensor of claim 13, wherein a first surface of the buried insulation pattern positioned at a bottom of the trench contacts the silicon oxide layer.

15. The image sensor of claim 13, wherein a gate of the transistor is formed on an upper surface of the second semiconductor layer pattern.

16. The image sensor of claim 15, wherein the first semiconductor layer includes one or more inner surfaces at least partially defining an opening in the first semiconductor layer, and an insulation pattern fills the opening.

17. The image sensor of claim 16, further comprising a first through silicon via electrically connected to the transistor on the intermediate substrate,
wherein the first through silicon via extends through the buried insulation pattern, the silicon oxide layer, and the insulation pattern in the opening, and the first through silicon via extends to the floating diffusion region of the upper substrate from the intermediate substrate.

18. The image sensor of claim 15, wherein the image sensor includes a pixel array region and a signal processing region, and the image sensor further includes a second through silicon via extending through the upper substrate and the intermediate substrate, the second through silicon via located in the signal processing region.

19. An image sensor, comprising:
a lower device on a lower substrate, the lower device including a logic transistor;
a first insulating interlayer covering the lower device;
an intermediate device on a first surface of an intermediate substrate on the lower substrate, the intermediate device including at least one transistor;
a second insulating interlayer covering the intermediate device;
a first bonding pad pattern in the second insulating interlayer, an upper surface of the first bonding pad pattern exposed by a first surface of the second insulating interlayer;
an upper device on an upper substrate on the intermediate substrate, the upper device including a photodiode and a floating diffusion region;
a third insulating interlayer covering the upper device; and
a second bonding pad pattern in the third insulating interlayer, an upper surface of the second bonding pad pattern exposed by a first surface of the third insulating interlayer,
wherein a surface of the first insulating interlayer and a second surface opposite to the first surface of the intermediate substrate are bonded to each other,
wherein the first bonding pad pattern and the second bonding pad pattern are bonded to each other,
wherein the intermediate substrate includes a stack of a first semiconductor layer, a silicon oxide layer, and a second semiconductor layer pattern, and
wherein at least one sidewall surface of the second semiconductor layer pattern at least partially defines a trench extending through the second semiconductor layer pattern, and a buried insulation pattern fills the trench extending through the second semiconductor layer pattern.

20. The image sensor of claim 19, wherein a gate of the transistor is on an upper surface of the first semiconductor layer.
